(19) United States
(12) Patent Application Publication
(10) Pub. No.: US 2025/0208523 A1
(43) Pub. Date: Jun. 26, 2025

(54) BIPOD, OPTICAL SYSTEM AND PROJECTION EXPOSURE APPARATUS

(71) Applicant: Carl Zeiss SMT GmbH, Oberkochen (DE)

(72) Inventors: Sonia Anaelle Bissie, Aalen (DE); Tobias Hegele, Aalen (DE); Dietmar Duerr, Dettingen (DE)

(21) Appl. No.: 19/074,961

(22) Filed: Mar. 10, 2025

Related U.S. Application Data
(63) Continuation of application No. PCT/EP2023/075738, filed on Sep. 19, 2023.

(30) Foreign Application Priority Data
Sep. 20, 2022 (DE) 102022209902.8

(51) Int. Cl. G03F 7/00

(52) U.S. Cl. CPC G03F 7/70825

(57) ABSTRACT

A bipod for adjusting an optical element of an optical system for a projection exposure apparatus, having a mechanism which is couplable to the optical element to adjust the optical element, a base portion, a first tower portion extending out of the base portion, and a second tower portion different from the first tower portion and extending out of the base portion. The mechanism is between the first and second tower portions. The first and second tower portions are connected to each other facing away from the base portion to increase the stiffness of the bipod.

### CROSS-REFERENCE TO RELATED APPLICATIONS

The present application is a continuation of, and claims benefit under 35 USC 120 to, international application No. PCT/EP2023/075738, filed Sep. 19, 2023, which claims benefit under 35 USC 119 of German Application No. 10 2022 209 902.8, filed Sep. 20, 2022. The entire disclosure of each of these applications is incorporated by reference herein.

### FIELD

The present disclosure relates to a bipod for adjusting an optical element of an optical system for a projection exposure apparatus, to an optical system having such a bipod, and to a projection exposure apparatus having such a bipod and/or such an optical system.

### BACKGROUND

Microlithography is used for the production of microstructured components, for example integrated circuits. The microlithography process is carried out using a lithography apparatus, which has an illumination system and a projection system. The image of a mask (reticle) illuminated with the aid of the illumination system is projected here with the aid of the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, DUV lithography apparatuses (deep ultraviolet, DUV) are currently under development, which use light having a wavelength in the range of 30 nanometers (nm) to 250 nm, such as 193 nm. In the case of such DUV lithography apparatuses, reflective optical units, that is to say mirrors, can be used instead of, as hitherto, refractive optical units, that is to say lens elements.

What are known as manipulators or bipods can be used to adjust mirrors of the projection system as mentioned above. Each mirror can be assigned three bipods. With the aid of these three bipods, it is possible to adjust the respective mirror in six degrees of freedom. In order to optimize the dynamics of such a system, the highest possible stiffness is desirable. At the same time, however, the ability to adjust the mirror should not be restricted.

### SUMMARY

The present disclosure seeks to provide an improved bipod.

Accordingly, a bipod for adjusting an optical element of an optical system for a projection exposure apparatus is proposed. The bipod comprises a mechanism, which is couplable to the optical element in order to adjust the optical element, a base portion, a first tower portion extending out of the base portion, a second tower portion, which differs from the first tower portion and likewise extends out of the base portion, wherein the mechanism is arranged between the first tower portion and the second tower portion, and wherein the first tower portion and the second tower portion are connected to each other facing away from the base portion in order to increase the stiffness of the bipod.

Due to the fact that the first tower portion and the second tower portion are connected to each other, it is possible to increase the stiffness of the bipod. This can help allow the dynamics of the bipod or the optical system to be optimized. With dynamic excitation of the bipod, vibrations of the tower portions can thus be reliably avoided. A high-precision adjustment of the optical element is possible without vibration influences.

The bipod can also be called a manipulator. A plurality of such bipods can be assigned to the optical system. The optical element can be a mirror, such as a DUV mirror. The optical element has an optically effective surface, which is configured to reflect illumination radiation, such as DUV radiation. The optically effective surface may be a mirror surface. However, the optical element may also be a lens element or the like.

The optical system can be a projection optical unit or a part of a projection optical unit of the projection exposure apparatus. The optical system can therefore also be called a projection optical unit or projection lens. Alternatively, the optical system may also be an illumination optical unit or a part of such an illumination optical unit. However, the following assumes that the optical system is a projection optical unit as mentioned above or a part of such a projection optical unit. The optical system can have a plurality of optical elements.

A coordinate system having a first spatial direction or x-direction, a second spatial direction or y-direction and a third spatial direction or z-direction is assigned to the bipod or optical system. The spatial directions are aligned perpendicular to one another. The optical element or the optically effective surface has six degrees of freedom, to be specific three translational degrees of freedom each along the x-direction, the y-direction and the z-direction, and three rotational degrees of freedom each around the x-direction, the y-direction and the z-direction. That is to say that a position and an orientation of the optical element or of the optically effective surface can be determined or described with the aid of the six degrees of freedom.

The “position” of the optical element or of the optically effective surface are understood to mean in particular the coordinates thereof or the coordinates of a measurement point provided on the optical element with respect to the x-direction, the y-direction and the z-direction. The “orientation” of the optical element or of the optically effective surface is understood to mean in particular its tilt with respect to the three spatial directions. That is to say that the optical element or the optically effective surface can be tilted about the x-direction, the y-direction and/or the z-direction.

This results in the six degrees of freedom for the position and/or orientation of the optical element or of the optically effective surface. A “pose” of the optical element or of the optically effective surface can encompass both its position and its orientation. The term “pose” is accordingly replaceable by the wording “position and orientation”, and vice versa.

An “adjustment” or “alignment” of the optical element or the optically effective surface is understood to mean in particular a change in the pose of the optical element or the optically effective surface. For example, the optical element can be moved from an actual position to a target position and vice versa with the aid of the bipod or with the aid of a plurality of bipods. The adjustment or alignment of the optical element or the optically effective surface can thus be carried out in all six abovementioned degrees of freedom.

The mechanism can also be called kinematics. The mechanism can comprise a coupling element, which can be operatively connected or coupled to the optical element. For example, the optical element has a plurality of mirror sockets on its rear side, wherein each mirror socket can be assigned one bipod, which is operatively connected to the respective coupling element. For this purpose, an intermediate frame between the bipod or the bipods and the optical element may be provided.

The mechanism can comprise a plurality of lever arms, which are connected to one another with the aid of flexures, as they are known. A “flexure” is generally understood to mean a region, for example a cross-sectional narrowing or thinning, of a component, which region enables a relative movement between two rigid-body regions of the component by bending. In this case, the lever arms form the rigid-body regions, which are movably connected to one another with the aid of the flexures.

The mechanism is configured to convert a travel of an actuating element into a movement of the aforementioned coupling element with the aid of the aforementioned lever arms and/or flexures. The movement can be converted here with a defined transmission ratio. Furthermore, the mechanism is also suitable for converting a direction of effect of the actuating element into a differently oriented movement of the coupling element. The actuating element can be part of the mechanism. A plurality of actuating elements can be provided. The actuating element or the actuating elements are thus in particular configured to move the coupling element via the aforementioned lever arms and flexures.

For example, the mechanism is suitable for moving and/or tilting the coupling element in a translational or linear manner. Either a purely linear movement, a purely tilting movement or a combined linear and tilting movement of the coupling element can be effected. For example, the mechanism can move the coupling element linearly along one of the aforementioned spatial directions and tilt it about another of the aforementioned spatial directions.

For example, the mechanism can move the coupling element linearly along the z-direction and tilt it about the x-direction. The mechanism is thus configured to change or adjust a pose of the coupling element in two degrees of freedom. By combining a plurality of such bipods which together adjust the optical element, it is thus possible to move the optical element in all six degrees of freedom and thus change its pose.

The mechanism can comprise exactly two actuating elements or actuators. The actuating elements can be piezo elements. The actuating elements are arranged in suitable pockets provided in or on the mechanism. The actuating elements can perform a linear movement, which is transferred to the coupling element with the aid of the mechanism. With the aid of the aforementioned lever arms and/or flexures it is possible to convert the travel of the respective actuating element into a movement of the coupling element.

The base portion is for example bar-shaped or strip-shaped. The base portion may extend along one of the aforementioned spatial directions, for example along the y-direction. The base portion has a first end portion and a second end portion. At the first end portion, the first tower portion is provided. At the second end portion, the second tower portion is provided. The first tower portion and the second tower portion are both arranged perpendicular to the base portion. For example, the tower portions extend along the z-direction perpendicular to the y-direction. The base portion and the tower portions thus form a U-shaped geometry. For example, the first tower portion, the second tower portion and the mechanism at the top extend out of the base portion.

The base portion, the first tower portion and the second tower portion form a one-piece component, in particular a component made of one piece of material. “One piece” or “one part” means here in particular that the base portion, the first tower portion and the second tower portion are not composed of different subcomponents, but form a common component. “Made of one piece of material” means here that the base portion, the first tower portion and the second tower portion are made of the same material throughout. In particular, the mechanism can also be formed in one piece, such as in one piece of material, with the base portion. The mechanism can therefore be part of the base portion or vice versa.

The fact that the second tower portion “differs” from the first tower portion means in particular that the first tower portion and the second tower portion are not identical, but form two separate portions or regions of the bipod. The first tower portion and the second tower portion are arranged spaced apart, for example viewed along the y-direction, wherein the aforementioned mechanism is arranged between the first tower portion and the second tower portion.

For example, the mechanism is arranged viewed along the y-direction between the first tower portion and the second tower portion. The tower portions can each have a rectangular cross-sectional geometry. The base portion can also have a rectangular cross-sectional geometry. The bipod can be in the form of a panel. In particular, “in the form of a panel” is understood to mean here that a geometric extent of the bipod viewed along the y-direction and the z-direction can be significantly larger than viewed along the x-direction.

A first joining point for joining the bipod to a fixed world, for example to what is known as a force frame, can be provided at the first tower portion. Accordingly, a second joining point for joining to the fixed world can be provided at the second tower portion. The joining points can be, for example, threaded holes. The tower portions can therefore also be called assembly towers, since they can be used to enable joining or mounting to the fixed world. The joining points are provided at an end or end portion of the respective tower portion facing away from the base portion. Thus, the joining points are not provided on the base portion itself, but on the tower portions. The joining points can thus be arranged upwardly offset with respect to the base portion viewed along the z-direction.

As previously mentioned, the first tower portion and the second tower portion are each connected by a first end or first end portion in one piece, in particular in one piece of material, to the base portion. The first tower portion and the second tower portion are connected to each other at a second end or second end portion of the respective tower portion facing away from the base portion. For this purpose, for example a stiffening element may be provided, which is firmly connected, for example screw-connected, to the first tower portion and the second tower portion. “Remote(ly) from” the base portion thus means that the tower portions are connected to each other not at their first ends or end portions, but at their second ends or end portions. This connection allows force to be transferred from the first tower portion to the second tower portion and vice versa.

The “stiffness” is generally understood to mean the resistance of a body, presently of the bipod or the tower portions, against an elastic deformation applied by an external load. This external load may include forces and/or moments. The stiffness is determined by the material used in the deformed body and its geometry. The geometry of the bipod and in particular of the mechanism can thus be optimized to achieve the greatest possible stiffness. The higher the stiffness, the better the dynamic behaviour.

According to one embodiment, the base portion, the first tower portion, the second tower portion and the mechanism form a one-piece component, in particular a component made of one piece of material.

This means in particular that the base portion, the first tower portion, the second tower portion and the mechanism are not composed of different substructures, but form one common component. The abovementioned lever arms and flexures can be manufactured by ablative manufacturing methods. For example, the lever arms can be produced with the aid of milling methods, wherein the flexures can be produced with the aid of erosion methods. Slots or cutouts are accordingly provided between the lever arms so that the lever arms can move about the flexures.

According to an embodiment, a first cutout is provided between the first tower portion and the mechanism, with a second cutout being provided between the second tower portion and the mechanism.

The cutouts may also be referred to as slots or gaps. The first cutout is used to separate or decouple the first tower portion from the mechanism. Accordingly, the second tower portion is separated or decoupled from the mechanism with the aid of the second cutout. The mechanism cannot therefore apply direct forces to the tower portions. Conversely, the tower portions thus cannot apply any forces to the mechanism either. The tower portions are therefore optionally not directly connected to the mechanism, but rather mechanically decoupled therefrom.

According to an embodiment, the mechanism has a first pocket for receiving a first actuating element and a second pocket for receiving a second actuating element, wherein the pockets are closed at the rear.

Exactly two actuating elements can be provided. The actuating elements can be piezo actuators. The actuating elements can be referred to as actuators. For example, the actuating elements are linear actuating elements or linear actuators. With the aid of the actuating elements it is possible to deflect the previously mentioned lever arms of the mechanism in order to move the coupling element in this way and change its pose. The first pocket and the second pocket each have a rear wall. In particular, this means that the pockets do not extend fully through the mechanism. With the aid of the rear-side closing of the pockets, a higher local stiffness of the mechanism can be achieved in the region of the pockets.

According to an embodiment, the bipod further comprises a stiffening element, which connects the first tower portion and the second tower portion facing away from the base portion.

The stiffening element is provided in particular on the rear side on the bipod. In particular, “rear (side)” means that the stiffening element is placed facing away from the actuating elements. The stiffening element can be in the form of a panel. Therefore, the stiffening element can also be referred to as a stiffening panel. The terms “stiffening element” and “stiffening panel” can therefore be interchanged as desired. The stiffening element can be, for example, a steel sheet or an aluminium sheet. The stiffening element may be connected to the first tower portion and the second tower portion with the aid of fastening points. At these fastening points, the stiffening element may be screw-connected to the tower portions.

According to an embodiment, the stiffening element is connected to the base portion.

For this purpose, the stiffening element has further joining points. For example, two joining points are provided for connecting the stiffening element to the base portion. The stiffening element can be screw-connected to the base portion at these joining points.

According to an embodiment, the stiffening element has facing away from the bipod a recess.

For example, the recess is positioned facing away from the mechanism and/or the tower portions. The stiffening element can comprise a front side, with the aid of which the stiffening element abuts the tower portions, and a rear side, on which the recess is provided. By providing the recess, it is possible to create sufficient installation space for further components that are placed adjacent to the bipod.

According to an embodiment, the recess has a plurality of recess portions, which extend into the stiffening element to different depths, as a result of which the recess has a stepped geometry.

For example, a first recess portion, a second recess portion and a third recess portion are provided. The second recess portion is deeper than the first recess portion, and the third recess portion is deeper than the second recess portion. Thus, a stepped or stair-type geometry of the recess facing away from the tower portions is obtained.

According to an embodiment, the bipod further comprises an exoskeleton which connects the first tower portion and the second tower portion facing away from the base portion.

“Facing away from” the base portion in this case means in particular that the first tower portion and the second tower portion are connected to each other at the ends or end portion of the respective tower portions which are facing away from the base portion, with the aid of the exoskeleton. The exoskeleton can also be referred to as a stiffening skeleton or stiffening portion. The terms “exoskeleton”, “stiffening skeleton” and “stiffening portion” can therefore be interchanged as desired. An “exoskeleton” can very generally be understood herein to mean a component or a portion of the bipod which connects the first tower portion facing away from the base portion to the second tower portion, in order to stiffen the bipod.

According to an embodiment, the first tower portion, the second tower portion and the exoskeleton are connected to one another in a single piece, in particular in a single piece of material.

For example, the mechanism is also connected in one piece, in particular in one piece of material, to the base portion, which in turn is connected in one piece, in particular in one piece of material, to the first tower portion and the second tower portion. However, the exoskeleton itself is not connected to the mechanism. Corresponding slots or cutouts are provided for this purpose between the exoskeleton and the mechanism, which enable movement of the mechanism or the lever arms and the flexures of the mechanism.

According to an embodiment, the mechanism is arranged at least in portions within the exoskeleton.

For example, this means that the exoskeleton encloses or surrounds the mechanism at least partially. For example, the exoskeleton comprises a bar-shaped base portion which is connected to the first tower portion via a first connecting portion and to the second tower portion via a second connecting portion. An opening may be provided in the base portion, through which the movable coupling element is guided. The coupling element can therefore be moved within this opening.

According to an embodiment, the base portion, the first tower portion, the second tower portion and the exoskeleton form a frame-type geometry, which extends completely around the mechanism.

For example, the base portion and the exoskeleton form two portions of a frame of the bipod running along the y-direction, with the tower portions forming two portions of the frame running along the z-direction. The mechanism is thus arranged within this frame-type geometry or within this frame formed from the base portion, the tower portions and the exoskeleton.

An optical system for a projection exposure apparatus is further proposed. The optical system comprises an optical element and at least one such bipod, wherein the at least one bipod is coupled to the optical element with the aid of the mechanism.

As previously mentioned, the optical system may be an illumination optical unit or a projection optical unit of the projection exposure apparatus. The optical system can have a plurality of optical elements. The bipod is operatively connected to the optical element with the aid of the abovementioned coupling element. The aforementioned intermediate frame may be provided between the bipod and the optical element. The optical element may have a plurality of mirror sockets on the underside, wherein the coupling element of the bipod is operatively connected to one of these mirror sockets.

According to one embodiment, the optical system further comprises a first bipod, a second bipod and a third bipod, wherein the optical element is adjustable in six degrees of freedom to bring the optical element from an actual pose into a target pose and vice versa, and wherein each bipod is assigned two of the six degrees of freedom.

For example, exactly three bipods are provided. Each bipod can be assigned to one mirror socket of the optical element. The bipods may be suitable for deflecting the aforementioned intermediate frame that supports the optical element. However, the intermediate frame is optional. The optical element can be moved from its actual pose to its target pose and vice versa with the aid of the bipods. For example, the optical element in the target pose meets specific optical specifications or desired properties that the optical element in the actual pose does not meet. In order to move the optical element from the actual pose to the target pose, the optical system comprises an adjustment device. The adjustment device may comprise the three bipods.

In addition, the adjustment device comprises an open-loop and closed-loop control unit, which is configured to control the bipods, in particular the actuating elements of the bipods, to adjust or align the optical element.

Furthermore, a projection exposure apparatus having such a bipod and/or such an optical system is proposed.

The optical system can be a projection optical unit of the projection exposure apparatus. However, the optical system can also be an illumination optical unit of the projection exposure apparatus. The projection exposure apparatus may be an EUV lithography apparatus. EUV stands for “extreme ultraviolet” and refers to a wavelength of the working light of between 0.1 nm and 30 nm. The projection exposure apparatus may also be a DUV lithography apparatus.

DUV stands for “deep ultraviolet” and refers to a wavelength of the working light of between 30 nm and 250 nm.

“A” or “an” or “one” in the present case should not necessarily be understood to be restrictive to exactly one element. Rather, a plurality of elements, such as two, three or more, may be provided. Nor should any other numeral used here be understood to the effect that there is a restriction to exactly the stated number of elements. Instead, unless indicated otherwise, numerical deviations upward and downward are possible.

The embodiments and features described for the bipod are correspondingly applicable to the proposed optical system and/or to the proposed projection exposure apparatus, and vice versa.

Further possible implementations of the disclosure also include combinations which were not mentioned explicitly of features or embodiments described above or hereinafter with respect to the exemplary embodiments. In this case, a person skilled in the art will also add individual aspects as improvements or supplementations to the respective basic form of the disclosure.

Further configurations and aspects of the disclosure are the subject of the dependent claims and also of the exemplary embodiments of the disclosure that are described hereinafter. In addition, the disclosure is explained in more detail on the basis of embodiments with reference to the enclosed figures.

### BRIEF DESCRIPTION OF THE DRAWINGS

FIG. 1 shows a schematic meridional section of a projection exposure apparatus for DUV projection lithography;

FIG. 2 shows a schematic view of an embodiment of an optical system for the projection exposure apparatus according to FIG. 1;

FIG. 3 shows a schematic top view of the optical system according to FIG. 2;

FIG. 4 shows a schematic front view of an embodiment of a bipod for the optical system in accordance with FIG. 2;

FIG. 5 shows a schematic rear view of the bipod according to FIG. 4; and

FIG. 6 shows a schematic front view of a further embodiment of a bipod for the optical system according to FIG. 2.

### DETAILED DESCRIPTION

Unless indicated otherwise, elements that are identical or functionally identical have been provided with the same reference signs in the figures. It should also be noted that the illustrations in the figures are not necessarily true to scale.

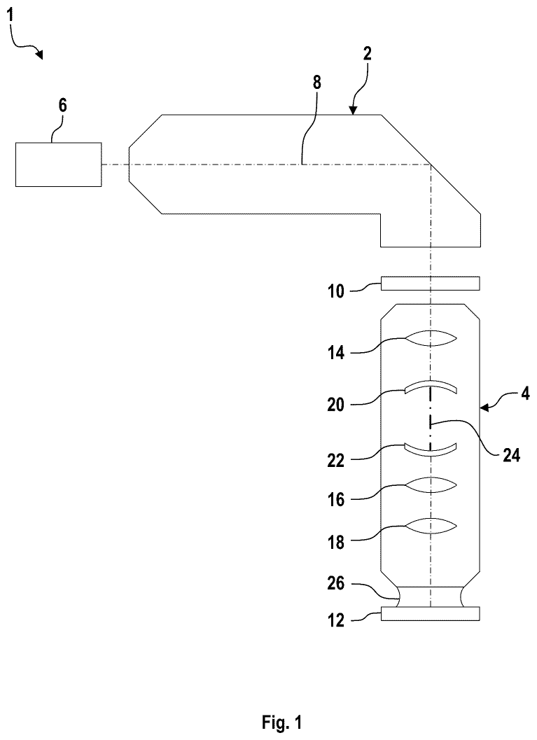

FIG. 1 shows a schematic view of a projection exposure apparatus 1, in particular a DUV lithography apparatus, which comprises a beam-shaping and illumination system 2 (also referred to herein as “illumination optical unit”) and a projection optical unit 4 (also referred to herein as “projection lens”). In this case, DUV stands for “deep ultraviolet” and denotes a wavelength of the working light of between 30 nm and 250 nm. The beam-shaping and illumination system 2 and the projection optical unit 4 can each be arranged in a vacuum housing (not shown). Each vacuum housing is evacuated with the aid of an evacuation apparatus (not illustrated). The vacuum housings are surrounded by a machine room (not illustrated), in which driving apparatuses for mechanically moving or setting optical elements can be provided. Furthermore, electrical controllers and the like may also be arranged in the machine room.

The projection exposure apparatus 1 has a light source 6. For example, an ArF excimer laser that emits radiation 8 in the DUV range, at for example 193 nm, may be provided as the light source 6. In the beam-shaping and illumination system 2, the radiation 8 is focused and the desired operating wavelength (working light) is filtered out from the radiation 8. The beam-shaping and illumination system 2 may have optical elements which are not illustrated, for example mirrors or lens elements.

After passing through the beam-shaping and illumination system 2, the radiation 8 is guided onto a photomask, or reticle 10. The photomask 10 is formed as a transmissive optical element and can be arranged outside the beam-shaping and illumination device 2 and the projection optical unit 4. The photomask 10 has a structure which is imaged on a wafer 12 in reduced form using the projection optical unit 4.

The projection optical unit 4 has a plurality of lens elements 14, 16, 18 and/or mirrors 20, 22 for imaging the photomask 10 onto the wafer 12. In this case, individual lens elements 14, 16, 18 and/or mirrors 20, 22 of the projection optical unit 4 can be arranged symmetrically relative to an optical axis 24 of the projection optical unit 4. It should be noted that the number of lens elements 14, 16, 18 and mirrors 20, 22 shown here is purely by way of example and is not restricted to the number shown. A greater or lesser number of lens elements 14, 16, 18 and/or mirrors 20, 22 may also be provided.

An air gap between a last lens element (not shown) and the wafer 12 can be replaced by a liquid medium 26 which has a refractive index of >1. The liquid medium 26 may be for example high-purity water. Such a set-up is also referred to as immersion lithography and has an increased photolithographic resolution. The medium 26 may also be referred to as an immersion liquid.

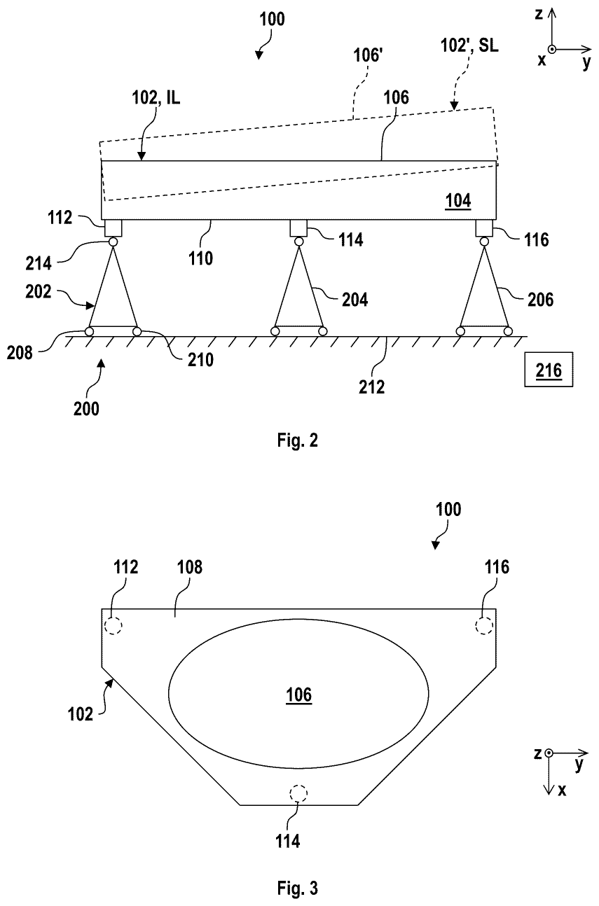

FIG. 2 shows a schematic view of an embodiment of an optical system 100 for the projection exposure apparatus 1. FIG. 3 shows a schematic top view of the optical system 100. In the following text, reference is made to FIGS. 2 and 3 simultaneously.

The optical system 100 may be a projection optical unit 4 as explained above or part of such a projection optical unit 4. Therefore, the optical system 100 can also be referred to as projection optical unit. However, the optical system 100 may also be a beam-shaping and illumination system 2 as previously explained, or part of such a beam-shaping and illumination system 2. Therefore, the optical system 100 can alternatively also be referred to as beam-shaping and illumination system. However, the following text assumes that the optical system 100 is a projection optical unit 4 or part of such a projection optical unit 4. The optical system 100 is suitable for DUV lithography. However, the optical system 100 can also be suitable for EUV lithography.

The optical system 100 may comprise a plurality of optical elements 102, of which only one is shown in FIGS. 2 and 3 however. Therefore, only one optical element 102 is discussed below. The optical element 102 may be one of the lens elements 14, 16, 18 or one of the mirrors 20, 22. The following text assumes that the optical element 102 is one of the mirrors 20, 22. The optical element 102 comprises a substrate 104 and an optically effective surface 106, for example a mirror surface. The substrate 104 can also be referred to as mirror substrate. The substrate 104 may comprise glass, ceramic, glass ceramic or other suitable materials.

The optically effective surface 106 is provided on a front side 108 of the substrate 104. The optically effective surface 106 can be realized with the aid of a coating applied to the front side 108. The optically effective surface 106 is a mirror surface. The optically effective surface 106 is suitable for reflecting illumination radiation, in particular DUV radiation, during operation of the optical system 100. The optically effective surface 106 may have an oval or elliptical geometry in the top view according to FIG. 3. The optical element 102 or the substrate 104 may have a triangular geometry. In general, however, the geometry is arbitrary.

The optical element 102 has a rear side 110 facing away from the optically effective surface 106 or the front side 108. The rear side 110 has no defined optical properties. That is to say in particular that the rear side 110 is not a mirror surface and therefore also does not have reflective properties.

A plurality of mirror sockets 112, 114, 116 are provided on the rear side 110. A first mirror socket 112, a second mirror socket 114 and a third mirror socket 116 are provided. In other words, the optical element 102 comprises exactly three mirror sockets 112, 114, 116. The mirror sockets 112, 114, 116 can have geometrically identical designs. The mirror sockets 112, 114, 116 are cylindrical and extend in the orientation of FIG. 2 on the underside out of the rear side 110. The mirror sockets 112, 114, 116 form corners of an imaginary triangle.

The optical element 102 or the optically effective surface 106 has six degrees of freedom, namely three translational degrees of freedom each along the first spatial direction or x-direction x, the second spatial direction or y-direction y and the third spatial direction or z-direction z, and three rotational degrees of freedom each about the x-direction x, the y-direction y and the z-direction z. That is to say that a position and an orientation of the optical element 102 or of the optically effective surface 106 can be determined or described with the aid of the six degrees of freedom.

The “position” of the optical element 102 or of the optically effective surface 106 is in particular understood to mean the coordinates thereof or the coordinates of a measurement point provided on the optical element 102 with respect to the x-direction x, the y-direction y, and the z-direction z. The “orientation” of the optical element 102 or of the optically effective surface 106 is understood to mean in particular its tilt with respect to the three spatial directions x, y, z. That is to say that the optical element 102 or the optically effective surface 106 can be tilted about the x-direction x, the y-direction y, and/or the z-direction z.

This results in the six degrees of freedom for the position and/or orientation of the optical element 102 or of the optically effective surface 106. A “pose” of the optical element 102 or of the optically effective surface 106 encompasses both its position and its orientation. The term “pose” is accordingly replaceable by the wording “position and orientation”, and vice versa.

FIG. 2 shows an actual pose IL of the optical element 102 or of the optically effective surface 106 in solid lines and a target pose SL of the optical element 102 or of the optically effective surface 106 in dashed lines and with the reference signs 102′ and 106′. The optical element 102 can be moved from its actual pose IL to the target pose SL and vice versa. For example, the optical element 102 in the target pose SL meets specific optical specifications or desired properties that the optical element 102 in the actual pose IL does not meet.

In order to move the optical element 102 from the actual pose IL to the target pose SL, the optical system 100 comprises an adjustment device 200. The adjustment device 200 is configured for adjusting the optical element 102. In particular, an “adjustment” or “alignment” is understood to mean herein a change in the pose of the optical element 102. For example, the optical element 102 can be moved from the actual pose IL to the target pose SL and vice versa with the aid of the adjustment device 200. The adjustment or alignment of the optical element 102 can thus be carried out with the aid of the adjustment device 200 in all six abovementioned degrees of freedom.

The adjustment device 200 comprises a plurality of manipulators or bipods 202, 204, 206, which are shown in FIG. 2 only highly schematically. Each mirror socket 112, 114, 116 is assigned one bipod 202, 204, 206. In particular, this means that exactly three bipods 202, 204, 206 are provided. Each bipod 202, 204, 206 may be assigned two of the abovementioned degrees of freedom. Using the three bipods 202, 204, 206, an adjustment of the optical element 102 in all six degrees of freedom is thus possible.

A first bipod 202 is assigned to the first mirror socket 112. A second bipod 204 is assigned to the second mirror socket 114. A third bipod 206 is assigned to the third mirror socket 116. The bipods 202, 204, 206 have identical designs. Therefore, only the first bipod 202 and the first mirror socket 112 are discussed below, which are simply referred to as bipod 202 and mirror socket 112, respectively.

The bipod 202 is coupled to a fixed world 212 with the aid of a first joining point 208 and a second joining point 210. The fixed world 212 can be a force frame or any other immovable structure. For example, the bipod 202 is connected to the fixed world 212 with the aid of screw connections at the joining points 208, 210. The bipod 202 further comprises a coupling element 214, which is coupled to the mirror socket 112 assigned to the bipod 202. An intermediate frame (not shown) may be provided between the coupling element 214 and the mirror socket 112.

The bipod 202 is assigned two actuators or actuating elements (not shown), which can be controlled with the aid of an open-loop and closed-loop control unit 216 of the adjustment device 200. All actuating elements of all bipods 202, 204, 206 are actively connected to the open-loop and closed-loop control unit 216, and as a result the open-loop and closed-loop control unit 216 can adjust the optical element 102 in all six degrees of freedom with the aid of a suitable control of these actuating elements.

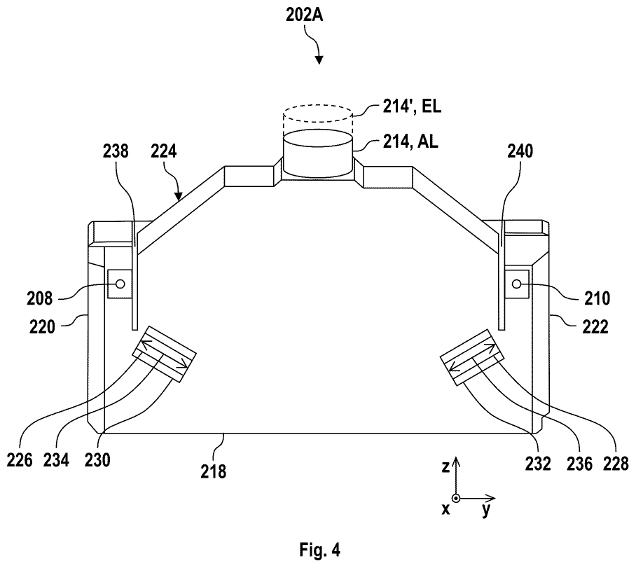

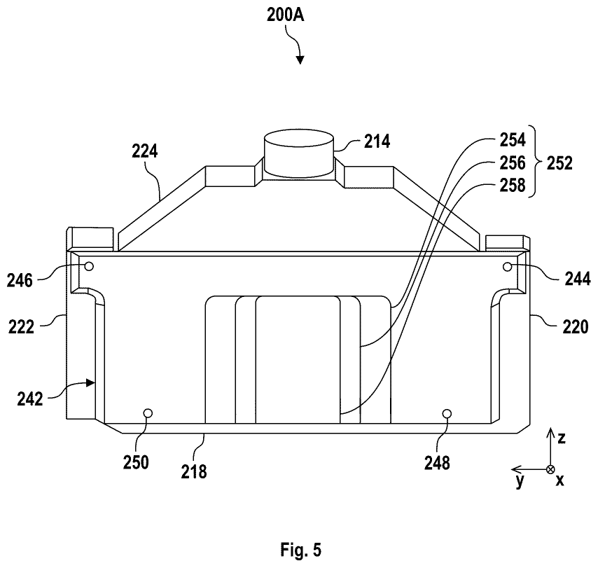

FIG. 4 shows a schematic front view of an embodiment of a bipod 202A as mentioned above FIG. shows a schematic rear view of the bipod 202A. In the following text, reference is made to FIGS. 4 and 5 simultaneously.

In order to increase the dynamics of the optical system 100 and the bipod 202A, an improved stiffness of the bipod 202A is desirable. The term “stiffness” is generally understood to mean herein the resistance of a component to an elastic deformation due to an external load, in particular a force and/or a moment. The stiffness provides a correlation between the load on the component and its deformation. The stiffness is determined by the material of the component and its geometry, in particular its shape and size.

The stiffening is effected constructively by adapting the design of the bipod 202A and also by attaching a stiffening structure or frame structure to be explained below, which gives the bipod 202A additional stiffness. In addition, kinematics or a mechanism of the bipod 202A, which will be explained below, are/is optimized in such a way that a high stiffness and high dynamics can be enabled at the same time.

Local deformations of the bipod 202A can contribute to a deterioration of the dynamic performance of the optical system 100 or the bipod 202A. The object here is to implement the stiffest possible structure in a limited installation space. As desired properties relating to dynamic behaviour increase, complexity generally increases. In this context, the desired properties relating to the bipod 202A with regard to its travel and its position accuracy as installation space becomes narrower are high. As a result of these desired properties, the bipod 202A is designed to be robust in order to increase its overall stiffness.

The bipod 202A has a geometry that is fundamentally in the form of a panel. “In the form of a panel” in this context means that a geometric extent of the bipod 202A viewed along the y-direction y and the z-direction z is significantly larger than viewed along the x-direction x. The cross section of the bipod 202A is substantially rectangular. However, the coupling element 214 can be cylindrical.

The bipod 202A comprises a bar-shaped base portion 218, which extends along the y-direction y in the orientation of FIGS. 4 and 5. A first tower portion 220 and a second tower portion 222 are respectively provided on the end sides of the base portion 218. The tower portions 220, 222 extend along the z-direction z and are thus arranged perpendicular to the base portion 218. The base portion 218 and the tower portions 220, 222 are formed in one piece, in particular in one piece of material.

“In one piece” or “one part” herein means in particular that the base portion 218 and the tower portions 220, 222 are not composed of a plurality of subcomponents, but form one common component. In particular, “in one piece of material” means that the base portion 218 and the tower portions 220, 222 are manufactured from the same material throughout. Suitable materials used are, for example, metallic materials, in particular aluminium alloys or steel alloys.

At the first tower portion 220, the first joining point 208 is provided, which can be, for example, a threaded hole. Thus, the first tower portion 220 is connected to the fixed world 212 with the aid of the first joining point 208. Accordingly, the second joining point 210, which can also be a threaded hole, is provided at the second tower portion 222. Thus, the second tower portion 222 is connected to the fixed world 212 with the aid of the second joining point 210.

When viewed along the y-direction y, the joining points 208, 210 are spaced apart from one another. When viewed along the z-direction z, the joining points 208, 210 are disposed above the base portion 218. The base portion 218 itself thus does not have the joining points 208, 210. The base portion 218 is thus free of joining points 208, 210. In other words, the basic portion 218 is joining-point-free or joining-point-less. The base portion 218 itself is therefore not directly connected to the fixed world 212.

Between the first tower portion 220 and the second tower portion 222, kinematics or a mechanism 224 is provided whose structural design is not explained in further detail. With the aid of the mechanism 224, it is possible to linearly move the coupling element 214 along the z-direction z and/or to tilt it about the x-direction x. Only a linear movement along the z-direction z, a linear movement along the y-direction y, a linear movement in a diagonal direction in a plane defined by the y-direction y and the z-direction z, or a linear movement combined with a rotational movement around the x-direction x may be performed. FIG. 4 shows a pure linear movement of the coupling element 214 along the z-direction z. The coupling element 214 is part of the mechanism 224.

It is thus possible to move the coupling element 214 in two degrees of freedom and thus to move it from a starting pose AL illustrated with solid lines into any end pose EL illustrated with dashed lines, in which the coupling element is provided with the reference sign 214′. A number of the end poses EL is arbitrary. In particular, any intermediate poses (not shown) can be set between the starting pose AL and the end pose EL.

The mechanism 224 has a first actuating element 226 and a second actuating element 228, which differs from the first actuating element 226. The actuating elements 226, 228 can also be referred to as actuators. The actuating elements 226, 228 are piezo actuating elements or piezo actuators or can be referred to as such. The mechanism 224 has a first pocket 230 in which the first actuating element 226 is received, and a second pocket 232 in which the second actuating element 228 is received. The pockets 230, 232 are closed at the rear in the orientation of FIG. 4.

As previously mentioned, the actuating elements 226, 228 are controllable with the aid of the open-loop and closed-loop control unit 216 to change the pose of the coupling element 214 or, with all three bipods 202, 202A, 204, 206 together, the pose of the optical element 102. For transferring a movement or a travel 234, 236 of the respective actuating element 226, 228 to the coupling element 214, the mechanism 224 comprises a multiplicity of lever arms (not shown), which are formed by cutouts, and flexures, about which the lever arms are pivotable.

For example, the respective travel 234, 236 can be increased with the aid of the mechanism 224 in the manner of a transmission. The mechanism 224 thus increases the respective travel 234, 236 towards the coupling element 214, with the result that a small deflection of the respective actuating element 226, 228 results in a greater deflection of the coupling element 214. The mechanism 224 may have a certain transmission ratio with which the respective travel 234, 236 is translated into a corresponding deflection of the coupling element 214.

With the exception of the actuating elements 226, 228, the mechanism 224 is a one-piece component, in particular a component made of one piece of material. The abovementioned lever arms can be manufactured by a milling method, wherein the flexures can be produced with the aid of an erosion method. The mechanism 224, the coupling element 214 and the base portion 218 form a one-piece component, in particular a component made of one piece of material. In particular, this means that the mechanism 224 can be part of the base portion 218 or vice versa.

Between the tower portions 220, 222 and the mechanism 224, a slot or cutout 238, 240 is provided in each case, so that the mechanism 224 is not directly connected to the tower portions 220, 222. A first cutout 238 and a second cutout 240 are provided. The first cutout 238 is provided between the first tower portion 220 and the mechanism 224. The second cutout 240 is provided between the second tower portion 222 and the mechanism 224.

Since the tower portions 220, 222 are not connected to the mechanism 224, it is possible that they deform in an undesirable manner. In order to increase the stiffness of the bipod 202A, a stiffening element 242 is provided which connects the tower portions 220, 222 to each other and thus stiffens the bipod 202A. The stiffening element 242 is in the form of a panel and can therefore also be referred to as a stiffening panel. The terms “stiffening element” and “stiffening panel” can therefore be interchanged as desired. The stiffening element 242 is part of the bipod 202A.

The stiffening element 242 can be manufactured from a metallic material, for example from a steel alloy or an aluminium alloy. The stiffening element 242 has a significantly reduced wall thickness viewed along the x-direction x compared with the bipod 202A. The stiffening element 242 may be sheet-like or be a sheet, in particular a steel sheet or an aluminium sheet.

The stiffening element 242 comprises a plurality of fastening points 244, 246, 248, 250. The fastening points 244, 246, 248, 250 can be openings or holes provided in the fastening element 242. Provided are a first fastening point 244, which is assigned to the first tower portion 220, a second fastening point 246, which is assigned to the second tower portion 222, a third fastening point 248, which is assigned to the base portion 218, and a fourth fastening point 250, which is also assigned to the base portion 218. The stiffening element 242 may be screw-connected to the tower portions 220, 222 at the fastening points 244, 246 and to the base portion 218 at the fastening points 248, 250.

Provided in the stiffening element 242 is a depression or recess 252 facing away from the bipod 202A, which extends viewed along the x-direction x into the stiffening element 242 in order to locally weaken or reduce its wall thickness. The recess 252 can be stepped and have a plurality of recess portions 254, 256, 258. A first recess portion 254, a second recess portion 256 and a third recess portion 258 are provided.

The second recess portion 256 extends viewed along the x-direction x deeper into the stiffening element 242 than the first recess portion 254, with the third recess portion 258 extending viewed along the x-direction x deeper into the stiffening element 242 than the second recess portion 256. Thus, a stepped or stair-type geometry of the recess 252 is obtained.

The bipod 202A is thus constructively adapted in the orientation of FIGS. 4 and 5 on the left and right of the base portion 218 in each case with a tower portion 220, 222. One respective joining point 208, 210 of the bipod 202A is disposed upwards to an end of the respective tower portion 220, 222 facing away from the base portion 218. Since the tower portions 220, 222 are connected to the base portion 218 only at one end and a respective connection cross section between the corresponding tower portion 220, 222 and the base portion 218 is relatively thin, dynamic excitation of the bipod 202A can cause undesirable vibrations of the tower portions 220, 222.

In order to suppress these vibrations of the tower portions 220, 222 and any associated deformation at a transition between the tower portions 220, 222 and the base portion 218, the tower portions 220, 222 and the base portion 218 are connected to one another with the aid of the stiffening element 242. The stiffening element 242 gives the tower portions 220, 222 additional stiffness.

Due to the narrow installation space, the stiffening element 242 is recessed externally, that is to say facing away from the tower portions 220, 222, with the aid of the recess 252 in order to provide a sufficient distance from neighbouring components. The rear-side recess 252 of the stiffening element 242 can serve as a movement space for bipod kinematics. In addition, the pockets 230, 232 are closed on one side. This local material reinforcement ensures a local stiffness increase in the region of the pockets 230, 232.

The mechanism 224 is optimized in the design of the bipod 202A. The flexures of the mechanism 224 are optimized regarding stress and stiffness. In addition, the alignment of a swivel joint in which a rotation region lies is adapted in order to achieve higher stiffness while maintaining joint stresses. The design of the bipod 202A allows the manufacturing process to be adapted. The contours of the bipod 202A are realized by milling and the flexures are eroded.

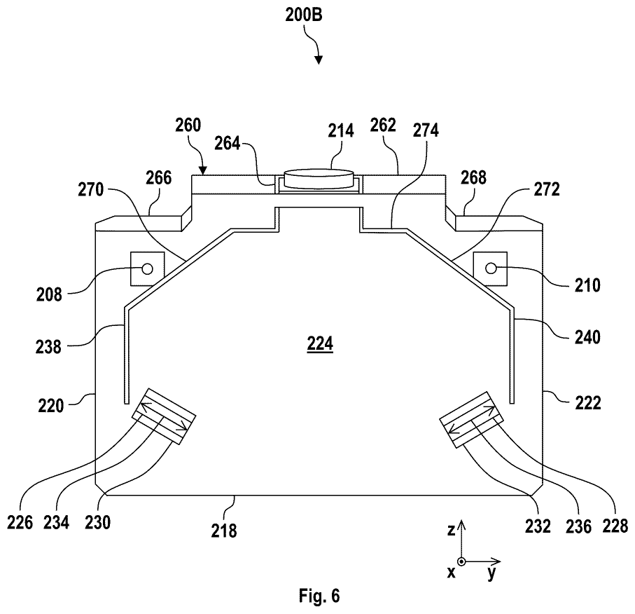

FIG. 6 shows a schematic front view of a further embodiment of a bipod 202B as mentioned above

The design of the bipod 202B is substantially the same as that of the bipod 202A. Therefore, only the differences between the two embodiments of bipod 202A, 202B are discussed below.

In contrast to the bipod 202A, the bipod 202B does not have a stiffening element 242 as previously explained, but has what is known as an exoskeleton 260. The exoskeleton 260 can also be referred to as a stiffening skeleton or stiffening portion. The terms “exoskeleton”, “stiffening skeleton” and “stiffening portion” can therefore be interchanged as desired.

The exoskeleton 260 connects the tower portions 220, 222 at an end of the tower portions 220, 222 facing away from the base portion 218. In this case, the tower portions 220, 222 and the exoskeleton 260 form a one-piece component, in particular a component made of one piece of material, In particular, the base portion 218, the first tower portion 220, the second tower portion 222, the mechanism 224 and the exoskeleton 260 form a one-piece component, in particular a component made of one piece of material.

The base portion 218, the two tower portions 220, 222 and the exoskeleton 260 form a frame-type geometry which extends completely around the mechanism 224 and thus encloses or surrounds it. The mechanism 224 is arranged at least in portions within the exoskeleton 260, or the exoskeleton 260 encloses the mechanism 224 at least partially.

The exoskeleton 260 has a base portion 262 with an opening 264 through which the coupling element 214 is guided. The coupling element 214 has sufficient clearance in the opening 264 for the coupling element 214, as previously mentioned, to be moved by the mechanism 224 to adjust its pose.

The base portion 262 is connected to the first tower portion 220 in one piece, in particular in one piece of material, with the aid of a first connecting portion 266. Furthermore, the base portion 262 is connected to the second tower portion 222 in one piece, in particular in one piece of material, with the aid of a second connecting portion 268. This thus results in a stepped geometry of the exoskeleton 260.

Between the first connecting portion 266 and the mechanism 224, a slot or cutout 270 is provided. Accordingly, a slot or cutout 272 is also provided between the second connecting portion 268 and the mechanism 224. A corresponding slot or cutout 274 is also provided between the base portion 262 and the mechanism 224.

The design of the bipod 202B includes the exoskeleton 260 and the base portion 218, which can include the mechanism 224. The exoskeleton 260 and the base portion 218 are monolithically connected to each other via the tower portions 220, 222 in order to enable stable joining points 208, 210 for the bipod 202B.

In addition, the exoskeleton 260 provides additional stiffness. Due to the larger overall width as a consequence of the exoskeleton 260, lateral auxiliary holes can be provided for the manufacture of radial decoupling joints. Furthermore, the geometry of the decoupling joints can be reproduced on the exoskeleton 260. The manufacturing processing of the pockets 230, 232 is adapted on the basis of the one-sided opening in order to meet the desired accuracy of functional surfaces.

Although the present disclosure has been described with reference to exemplary embodiments, it is modifiable in various ways.

### LIST OF REFERENCE SIGNS

1 Projection exposure apparatus
2 Beam-shaping and illumination system
4 Illumination optical unit
6 Light source
8 Radiation
10 Photomask
12 Wafer
14 Lens element
16 Lens element
18 Lens element
20 Mirror
22 Mirror
24 Optical axis
26 Medium
100 Optical system
102 Optical element
102 Optical element
104 Substrate
106 Optically effective surface
106′ Optically effective surface
108 Front side
110 Rear side
112 Mirror socket
114 Mirror socket
116 Mirror socket
200 Adjustment device
202 Bipod
202A Bipod
202B Bipod
204 Bipod
206 Bipod
208 Connecting point
210 Connecting point
212 Fixed world
214 Coupling element
214′ Coupling element
216 Open-loop and closed-loop control unit
218 Base portion
220 Tower portion
222 Tower portion
224 Mechanism
226 Actuating element
228 Actuating element
230 Pocket
232 Pocket
234 Travel
236 Travel
238 Cutout
240 Cutout
242 Stiffening element
244 Fastening point
246 Fastening point
248 Fastening point
250 Fastening point
252 Recess
254 Recess portion
256 Recess portion
258 Recess portion
260 Exoskeleton
262 Base portion
264 Opening
266 Connecting portion
268 Connecting portion
270 Cutout
272 Cutout
274 Cutout
AL Starting pose
EL End pose
IL Actual pose
M1 Mirror
M2 Mirror
M3 Mirror
M4 Mirror
M5 Mirror
M6 Mirror
SL Target pose
X x-direction
y y-direction
Z z-direction

What is claimed is:

1. A bipod, comprising:
a base portion;
a first tower portion extending from the base portion;
a second tower portion different from the first tower portion, the second tower portion extending from the base portion; and
a mechanism couplable to an optical element to adjust an optical element,
wherein:
the mechanism is between the first and second tower portions; and
the first and second tower portions are connected to each other facing away from the base portion.

2. The bipod of claim 1, wherein the base portion, the first tower portion, the second tower portion and the mechanism are a one-piece component.

3. The bipod of claim 2, wherein the base portion, the first tower portion, the second tower portion and the mechanism are one piece of material.

4. The bipod of claim 1, comprising:
a first cutout between the first and second tower portions; and
a second cutout between the second tower portion and the mechanism.

5. The bipod of claim 1, wherein the mechanism comprises:
a first pocket configured to receive a first actuating element; and
a second pocket configured to receive a second actuating element.

6. The bipod of claim 5, wherein the first pocket has a rear which is closed, and the second pocket has a rear which is closed.

7. The bipod of claim 5, comprising the first and second articulating elements.

8. The bipod of claim 1, further comprising a stiffening element connecting the first and second tower portions.

9. The bipod of claim 8, wherein the stiffening element is connected to the base portion.

10. The bipod of claim 8, wherein the stiffening element comprises a recess facing away from the bipod.

11. The bipod of claim 10, wherein the stiffening element comprises a plurality of recess portions extending into the stiffening element to different depths thereby defining a stepped geometry.

12. The bipod of claim 1, further comprising an exoskeleton connecting the first and section tower portions.

13. The bipod of claim 12, wherein the first tower portion, the second tower portion and the exoskeleton are one piece.

14. The bipod of claim 13, wherein the first tower portion, the second tower portion and the exoskeleton are one piece of material.

15. The bipod of claim 12, wherein at least portions of the mechanism are disposed within the exoskeleton.

16. The bipod of claim 12, wherein the base portion, the first tower portion, the second tower portion and the exoskeleton define a frame-type geometry extending completely around the mechanism.

17. The bipod of claim 1, wherein:
the mechanism comprises a first pocket configured to receive a first actuating element;
the mechanism comprises a second pocket configured to receive a second actuating element;
the bipod further comprises a stiffening element connecting the first and second tower portions; and
the bipod further comprises an exoskeleton connecting the first and section tower portions.

18. An optical system comprising:
an optical element; and
a first bipod according to claim 1 coupled to the optical element.

19. The optical system according to claim 18, further comprising:
a second bipod according to claim 1 coupled to the optical element; and
a third bipod according to claim 1 coupled to the optical element,
wherein each of the first, second and third bipods is assigned two of the six degrees of freedom.

20. An apparatus, comprising:
an optical element; and
a first bipod according to claim 1 coupled to the optical element,
wherein the apparatus is a projection exposure apparatus.
